(19) United States
(12) Patent Application Publication
(10) Pub. No.: US 2025/0185232 A1
(43) Pub. Date: Jun. 5, 2025

(54) SEMICONDUCTOR DEVICES

(71) Applicant: Samsung Electronics Co., Ltd., Suwon-si (KR)

(72) Inventors: Heonjun Ha, Suwon-si (KR); Jihoon Chang, Suwon-si (KR); Hana Cho, Suwon-si (KR)

(21) Appl. No.: 18/967,784

(22) Filed: Dec. 4, 2024

(30) Foreign Application Priority Data
Dec. 4, 2023 (KR) 10-2023-0173448
Mar. 12, 2024 (KR) 10-2024-0034718

(51) Int. Cl. H10B 12/00; H01L 23/31; H01L 23/528; H10D 1/68

(52) U.S. Cl. CPC H10B 12/315; H01L 23/3178; H01L 23/5283; H10D 1/716

(57) ABSTRACT

A semiconductor device includes a bit line extending in a first horizontal direction on a substrate, a channel layer on the bit line and extending in a vertical direction, a word line adjacent to a side wall of the channel layer and extending in a second horizontal direction crossing the first horizontal direction, a gate insulating layer between the channel layer and the word line, a contact layer on an upper side of the channel layer, a capping insulating layer covering at least a portion of the contact layer, an oxygen-containing insulating layer on at least a portion of the capping insulating layer, and a capacitor including a lower electrode that contacts at least a portion of an upper surface of the contact layer.

### CROSS-REFERENCE TO RELATED APPLICATIONS

This application is based on and claims priority under 35 U.S.C. § 119 to Korean Patent Application No. 10-2023-0173448, filed on Dec. 4, 2023, and Korean Patent Application No. 10-2024-0034718, filed on Mar. 12, 2024, in the Korean Intellectual Property Office, the disclosures of which are incorporated by reference herein in their entirety.

### BACKGROUND

Aspects of the inventive concept relate to semiconductor devices, and more particularly, to semiconductor devices including a capacitor structure.

With the downscaling of semiconductor devices, the size of dynamic random access memory (DRAM) devices is also being reduced. In the DRAM devices having a 1T-1C structure in which one capacitor is connected to one transistor, there is a problem in which leakage current through a channel region is increasing as the devices become smaller. To reduce the leakage current, transistors using an oxide semiconductor material as a channel layer were proposed.

### SUMMARY

Aspects of the inventive concept provide a semiconductor device with a reduced leakage current in a channel layer.

Aspects of the inventive concept provide a method for manufacturing a semiconductor device with a reduced leakage current in a channel layer.

According to an aspect of the inventive concept, a semiconductor device includes a bit line extending in a first horizontal direction on a substrate; a channel layer on the bit line and extending in a vertical direction; a word line adjacent to a side wall of the channel layer and extending in a second horizontal direction crossing the first horizontal direction; a gate insulating layer between the channel layer and the word line; a contact layer on an upper side of the channel layer; a capping insulating layer covering at least a portion of the contact layer; an oxygen-containing insulating layer on at least a portion of the capping insulating layer; and a capacitor comprising a lower electrode that contacts at least a portion of an upper surface of the contact layer.

According to an aspect of the inventive concept, a semiconductor device includes a bit line extending in a first horizontal direction on a substrate; a channel layer having a U-shape with a pair of opposing vertical extending portions that extend in a vertical direction on the bit line, wherein the pair of vertical extending portions each have an inner side wall and an outer side wall, the inner side wall of one of the pair of vertical extending portions facing the inner side wall of the other of the pair of vertical extending portions; a main mold layer covering at least a portion of the outer side wall of each of the pair of vertical extending portions of the channel layer, wherein a vertical level of a top surface of the main mold layer is below a vertical level of a top surface of the pair of vertical extending portions of the channel layer; a pair of word lines, each word line of the pair of word lines being adjacent to the inner side wall of a respective vertical extending portion of the pair of vertical extending portions, and extending in a second horizontal direction; a pair of gate insulating layers, each gate insulating layer of the pair of gate insulating layers being between the inner side wall of a respective vertical extending portion and a respective word line of the pair of word lines; a filling insulating layer between the pair of word lines; a pair of contact layers, each contact layer of the pair of contact layers being formed on an upper surface of a respective vertical extending portion of the channel layer; and capacitor structures each comprising a lower electrode contacting at least a portion of each contact layer of the pair of contact layers, respectively, wherein the channel layer comprises an oxygen-rich region in an upper portion of the channel layer, and the oxygen-rich region has an oxygen concentration greater than the oxygen concentration at a lower portion of the channel layer.

According to an aspect of the inventive concept, a semiconductor device includes a bit line extending in a first horizontal direction on a substrate; a channel layer comprising an oxide semiconductor material, the channel layer having a U-shape with a pair of opposing vertical extending portions that extend in a vertical direction on the bit line, wherein each of the pair of vertical extending portions has an inner side wall and an outer side wall, the inner side wall facing the inner side wall of the other one of the pair of vertical extending portions, and the channel layer comprises a first oxide semiconductor channel layer and a second oxide semiconductor channel layer formed on the first oxide semiconductor channel layer and having an oxygen concentration greater than that of the first oxide semiconductor channel layer; a main mold layer surrounding at least a portion of the outer side wall of each vertical extending portion of the pair of vertical extending portions of the channel layer, wherein a vertical level of a top surface of the main mold layer is below a vertical level of a top surface of the pair of vertical extending portions of the channel layer; a pair of opposing word lines that are adjacent to the opposing inner side walls of the channel layer, respectively, the pair of opposing word lines extending in a second horizontal direction; gate insulating layers, each gate insulating layer of the gate insulating layers being between the inner side wall of a respective vertical extending portion of the pair of vertical extending portions and a respective word line of the pair of word lines; a filling insulating layer between the pair of word lines; contact layers formed on an upper surface of each vertical extending portion of the pair of vertical extending portions of the channel layer; a capping insulating layer covering at least a portion of the contact layers; an oxygen-containing insulating layer formed on at least a portion of the capping insulating layer; and capacitor structures each comprising a lower electrode that respectively contact at least a portion of upper surfaces of the contact layers.

### BRIEF DESCRIPTION OF THE DRAWINGS

Embodiments will be more clearly understood from the following detailed description taken in conjunction with the accompanying drawings in which:

FIG. 1 is a layout showing a semiconductor device according to some embodiments;

FIG. 2 is an enlarged layout of a cell array region of FIG. 1;

FIG. 3 is a cross-sectional view of a semiconductor device taken along line A1-A1′ in FIG. 2, according to some embodiments;

FIG. 4 is a cross-sectional view of a semiconductor device taken along line A1-A1′ in FIG. 2, according to some embodiments;

FIG. 5 is a cross-sectional view of a semiconductor device taken along line A1-A1′ in FIG. 2, according to some embodiments;

FIG. 6 is a cross-sectional view of a semiconductor device taken along line A1-A1′ in FIG. 2, according to some embodiments;

FIGS. 7 to 18 are cross-sectional views showing a method of manufacturing a semiconductor device shown in FIG. 3 or 4, according to some embodiments; and

FIGS. 19 and 20 are cross-sectional views showing a method of manufacturing a semiconductor device shown in FIG. 5 or 6, according to some embodiments.

### DETAILED DESCRIPTION OF THE EMBODIMENTS

Hereinafter, some embodiments of the inventive concept will be described in detail with reference to the accompanying drawings.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

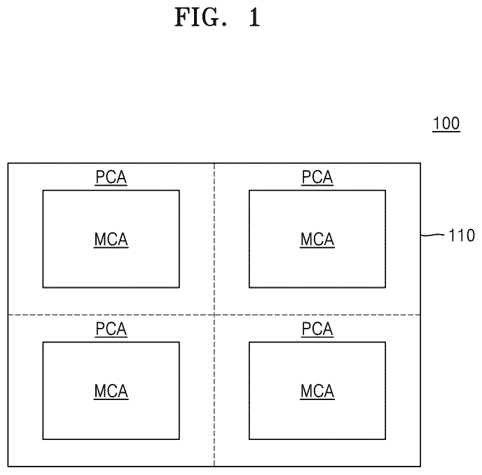

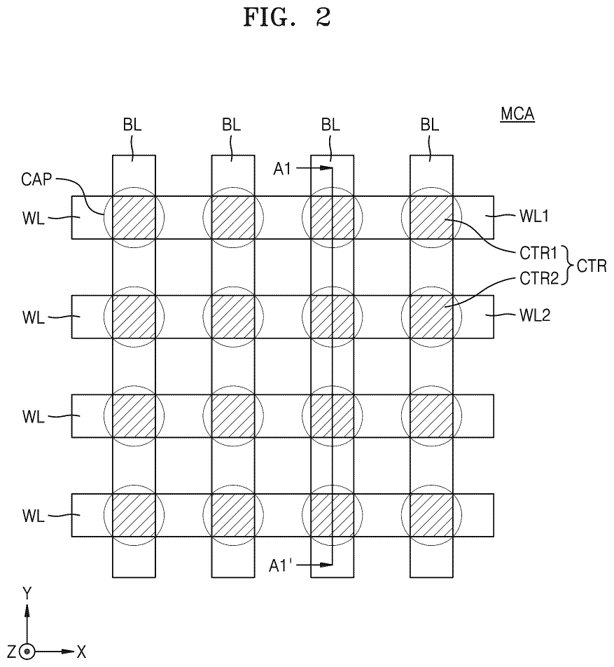

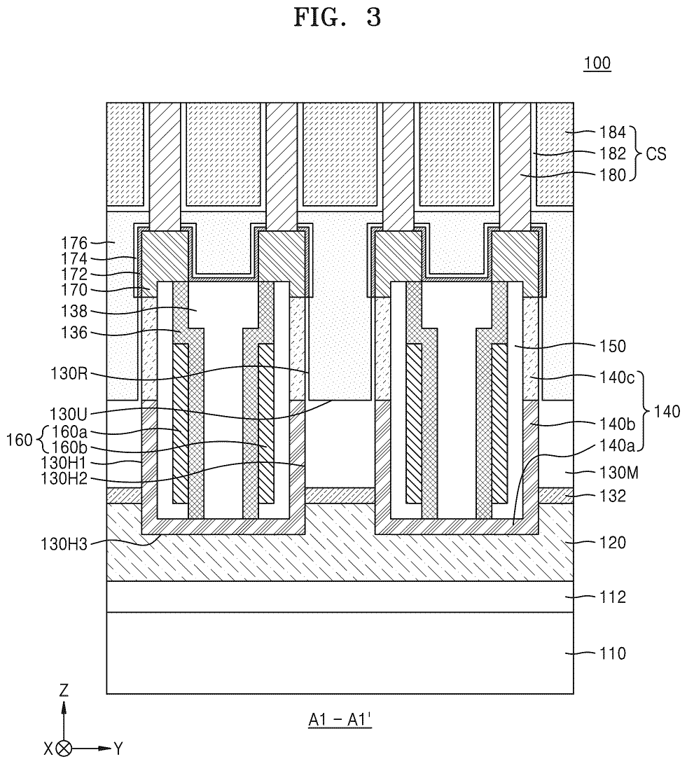

FIG. 1 is a layout showing a semiconductor device according to some embodiments. FIG. 2 is an enlarged layout of a cell array region of FIG. 1. FIG. 3 is a cross-sectional view of a semiconductor device taken along line A1-A1′ in FIG. 2, according to some embodiments.

Referring to FIGS. 1 to 3, a semiconductor device 100 may include a substrate 110 that include a cell array region MCA and a peripheral circuit region PCA. In some embodiments, the cell array region MCA may be a memory cell region of a dynamic random access memory (DRAM) device, and the peripheral circuit region PCA may be a core region or a peripheral circuit region of the DRAM device. For example, the peripheral circuit region PCA may include a peripheral circuit transistor (not shown) for transmitting signals and/or supplying power to a memory cell array contained in the cell array region MCA. In some embodiments, the peripheral circuit transistor (not shown) may constitute various circuits such as a command decoder, a control logic, an address buffer, a low decoder, a column decoder, a sense amplifier, and a data input and output circuit.

As shown in FIG. 2, a plurality of word lines WL that extend parallel to each other in a first horizontal direction X and a plurality of bit lines BL that extend parallel to each other in a second horizontal direction Y, perpendicular to the first direction, may be formed in the cell array region MCA of the substrate 110. A plurality of cell transistors CTR may be formed at intersections of the plurality of word lines WL and the plurality of bit lines BL. A plurality of cell capacitors CAP may be formed on the plurality of cell transistors CTR.

The plurality of word lines WL may include a first word line WL1 and a second word line WL2, which are alternately arranged in the second horizontal direction Y, and the plurality of cell transistors CTR may include a first cell transistor CTR1 and a second cell transistor CTR2, which are alternately formed in the second horizontal direction Y. The first cell transistor CTR1 may be formed on the first word line WL1, and the second cell transistor CTR2 may be formed on the second word line WL2.

The first cell transistor CTR1 and the second cell transistor CTR2 may have a mirror symmetrical structure with respect to each other. For example, the first cell transistor CTR1 and the second cell transistor CTR2 may have the mirror symmetrical structure with respect to a center plane between the first cell transistor CTR1 and the second cell transistor CTR2 extending in the first horizontal direction X and in a vertical direction Z. In addition, the cell transistor CTR may have a cross-point type that requires a relatively small unit area, so it may be advantageous for improving integration of the semiconductor device 100.

As shown in FIG. 3, a lower insulating layer 112 may be formed on the substrate 110. The substrate 110 may include silicon, such as single crystal silicon, polycrystalline silicon, or amorphous silicon. In some other embodiments, the substrate 110 may include at least one selected from Ge, SiGe, SiC, GaAs, InAs, and InP. In some embodiments, the substrate 110 may include a conductive region, such as a well doped with impurities, or a structure doped with impurities. The lower insulating layer 112 may include an oxide film, a nitride film, or a combination thereof.

A bit line 120 extending in the second horizontal direction Y may be formed on the lower insulating layer 112. In some embodiments, the bit line 120 may include Ti, TiN, Ta, TaN, W, WN, TiSiN, WSiN, polysilicon, or combinations thereof. In some embodiments, the bit line 120 may include a conductive barrier layer (not shown) formed on an upper surface and/or a lower surface of the bit line 120. A bit line insulating layer (not shown) extending in the second horizontal direction Y may be formed on side walls of the bit line 120. For example, referring to FIG. 2, the bit line insulating layer may fill a space between two adjacent bit lines BL with the same height as the bit line BL.

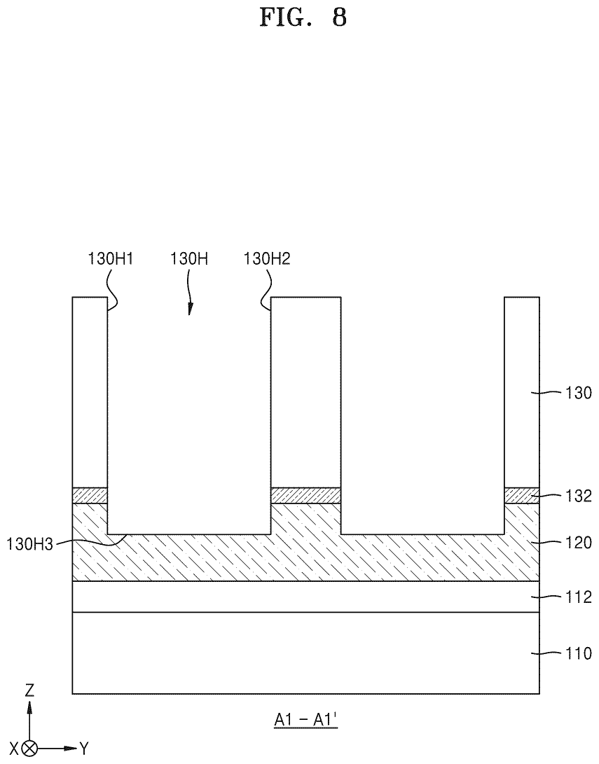

The first insulating layer 132 and a mold layer 130 (see FIG. 8) may be formed on the bit line 120 and the bit line insulating layer. As shown in FIG. 3, the mold layer 130 may include a main mold layer 130M and a residual mold layer 130R. The residual mold layer 130R may extend vertically from an upper surface of the main mold layer 130M. The first insulating layer 132 and the mold layer 130 may have etch selectivity to each other depending on etching conditions. The first insulating layer 132 may include an oxide-based insulating layer, a nitride-based insulating layer, or an oxynitride-based insulating layer. For example, the first insulating layer 132 may include a silicon oxide, a silicon nitride, or a silicon oxynitride. The mold layer 130 may include an oxide-based insulating layer, a nitride-based insulating layer, or an oxynitride-based insulating layer. For example, the mold layer 130 may include a silicon oxide, a silicon nitride, or a silicon oxynitride. In some embodiments, the first insulating layer 132 may include a silicon nitride (SiN), and the mold layer 130 may include tetraethyl orthosilicate (TEOS).

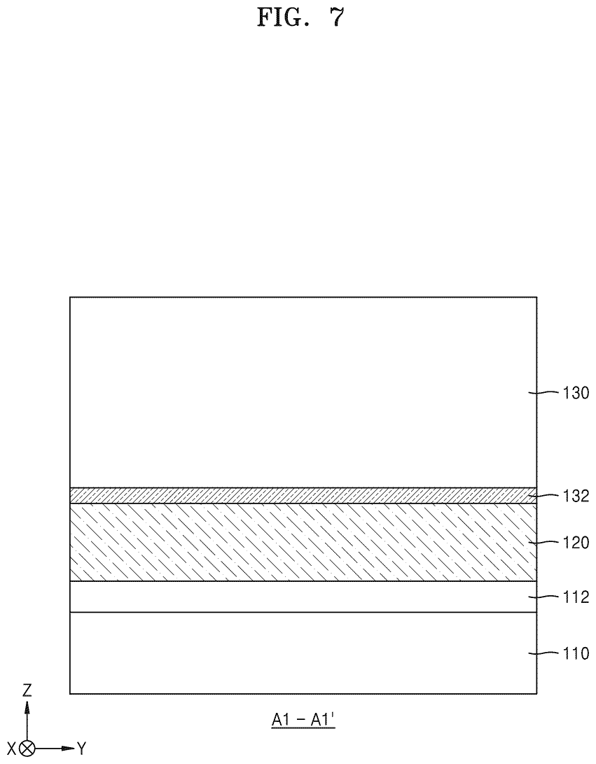

As described above, the mold layer 130 may include the main mold layer 130M and the residual mold layer 130R, but in some embodiments, the mold layer 130 may only include the main mold layer 130M without the residual mold layer 130R. The thickness of the residual mold layer 130R in the second horizontal direction Y may be very small compared to the thickness of the main mold layer 130M in the second horizontal direction Y. The mold layer 130 may include a plurality of mold openings 130H (see FIGS. 7 and 8). The plurality of mold openings 130H may include a first side wall 130H1 and a second side wall 130H2, which are opposite to each other, and the mold opening 130H may also include a bottom portion 130H3 between the first side wall 130H1 and the second side wall 130H2.

As shown in FIG. 3, the bottom portion 130H3 of the mold opening 130H may be formed at a recessed position at a certain depth below an upper surface of the bit line 120. In other words, the first side wall 130H1 and the second side wall 130H2 may extend below the upper surface of the bit line 120 while penetrating the first insulating layer 132. Thus, horizontal and vertical portions of the bit line 120 may be exposed to the mold opening 130H. In some embodiments, the bottom portion 130H3 of the mold opening 130H may be formed to match the upper surface of the bit line 120. In this case, the first insulating layer 132 on the bit line 120 may not be formed. In this case, only the upper surface of the bit line 120 may be exposed to the mold opening 130H.

A channel layer 140 may be formed on inner walls of each mold opening 130H. That is, the channel layer 140 having a predetermined thickness may be formed on the first side wall 130H1, the second side wall 130H2, and the bottom portion 130H3 of the mold opening 130H formed to have an approximately U-shaped vertical cross-section. The channel layer 140 may include a first channel portion 140a that extends in the second horizontal direction Y on the bottom portion 130H3 of the mold opening 130H when viewed in cross-section (see, e.g., FIG. 3), and may include a pair of opposing second channel portions 140b that are connected to both ends of the first channel portion 140a and extend in a vertical direction Z on the first side wall 130H1 and the second side wall 130H2 of the mold opening 130H when viewed in cross-section. The first channel portion 140a may be referred to as a horizontal extending portion of the channel layer 140, and the second channel portions 140b may be referred to as vertical extending portions of the channel layer 140. In some embodiments, a pair of opposing third channel portions 140c may be formed on upper portions of the second channel portions 140b as a portion of the second channel portion 140b, or separately from the second channel portions 140b. The third channel portion 140c may be an oxygen-rich region where an oxygen concentration in the third channel portion 140c is greater than the oxygen concentration in the first channel portion 140a and/or the second channel portion 140b.

Portions of outer side walls of the second channel portion 140b may be surrounded by the main mold layer 130M. In addition, other portions of the outer side walls of the second channel portion 140b may be surrounded by the first insulating layer 132 and the bit line 120. As described above, in some embodiments, when the first insulating layer 132 does not exist and the bottom portion 130H3 of the mold opening 130H is formed to match the upper surface of the bit line 120, portions of the outer side walls of the second channel portions 140b may be surrounded only by the main mold layer 130M.

FIG. 3 shows an embodiment in which a vertical level of a top surface of the second channel portion 140b matches the vertical level of a top surface 130U of the main mold layer 130M. In other words, the vertical level of the top surface of the second channel portion 140b and/or the vertical level of a bottom surface of the third channel portion 140c may match the vertical level of the top surface 130U of the main mold layer 130M. In some other embodiments, the vertical level of the top surface of the second channel portion 140b and/or the vertical level of a bottom surface of the third channel portion 140c may not match the vertical level of the top surface 130U of the main mold layer 130M. For example, the vertical level of the top surface of the second channel portion 140b and/or the vertical level of a bottom surface of the third channel portion 140c may be located at a position that is greater or less than the vertical level of the top surface 130U of the main mold layer 130M. On the other hand, the vertical level of the top surface of each channel layer 140 and/or the vertical level of a bottom surface of each third channel portion 140c may be located at a position that is greater than the vertical level of the top surface 130U of the main mold layer 130M.

In some embodiments, the channel layer 140 may include an oxide semiconductor material. The oxide semiconductor material may include oxygen, and may include at least one of IGZO (InGaZnOx), Sn-doped IGZO, W-doped IGZO, IZO (InZnOx), for example. As described above, the third channel portion 140c, which is the oxygen-rich region, may have an oxygen concentration greater than those of the first channel portion 140a and the second channel portion 140b. In some embodiments, the oxygen-rich region may be formed throughout the whole of the third channel portion 140c. In some other embodiments, the oxygen-rich region may be formed in a portion of the third channel portion 140c. In some embodiments, in the oxygen-rich region, the oxygen concentration may decrease linearly or non-linearly from the outer side wall toward the inner side wall of the channel layer 140. In some embodiments, in the oxygen-rich region, the oxygen concentration may decrease linearly by the diffusion distance of oxygen from the outer side wall toward the inner side wall of the channel layer 140. In some embodiments, the oxygen concentration may increase linearly or non-linearly from the second channel portion 140b to the oxygen-rich region or the third channel portion 140c.

The oxygen-rich region may be formed by performing an annealing treatment in an oxygen atmosphere for Vo passivation process (e.g., an oxygen vacancy passivation process), as described later in a method of manufacturing a semiconductor device according to some embodiments. Thus, the oxygen-rich region formed by performing the annealing treatment in the oxygen atmosphere may result in a decrease in oxygen vacancy (e.g., an increase in oxygen concentration) in the oxide semiconductor material that constitutes the third channel portion 140c. Therefore, as the leakage current of the channel layer 140 including the oxide semiconductor material decreases, the on/off characteristics and swing characteristics of a transistor may be improved, thereby improving the reliability of the semiconductor device including the transistor.

A gate insulating layer 150 and a word line 160 may be formed sequentially in the second horizontal direction Y on the inner side walls facing each other in one pair of channel layers 140 that are formed in one mold opening 130H. The gate insulating layer 150 and the word line 160 formed on each inner side wall of the pair of channel layers 140 that are formed within one mold opening 130H, may be formed symmetrically in the vertical cross-section. For example, the gate insulating layer 150 may be conformally formed in an L-shape in the vertical cross-section on the upper surface of the first channel portion 140a and on the inner side walls of the second channel portion 140b and the third channel portion 140c of the channel layer 140. The word lines 160 may be respectively formed on opposing inner side walls of the gate insulating layers 150 and may be formed symmetrically to face each other. That is, the gate insulating layer 150 may be between the word line 160 and the channel layer 140. The pair of opposing word lines 160 formed within one mold opening 130H may be referred to as a first word line 160a and a second word line 160b.

For example, the channel layer 140 having the U-shaped vertical cross-section may be formed within one mold opening 130H, and two word lines 160a and 160b may be formed on the channel layer 140 within one mold opening 130H to be spaced apart from each other. The gate insulating layer 150 may be provided between the channel layer 140 and the word line 160a, and between the channel layer and the word line 160b. Here, the first word line 160a may be placed to face a portion of the channel layer 140, and the second word line 160b may be placed to face another portion of the channel layer 140. The first word line 160a, the channel layer 140, and the gate insulating layer 150 therebetween may constitute the first cell transistor CTR1, and the second word line 160b, the channel layer 140, and the gate insulating layer 150 therebetween may constitute the second cell transistor CTR2. Thus, the first cell transistor CTR1 and the second cell transistor CTR2 may be arranged in a mirror symmetrical shape within one mold opening 130H.

The vertical level of a top surface of the gate insulating layer 150 may be equal to or higher than the vertical level of the top surface of the channel layer 140. In addition, the vertical level of the top surface of the word line 160 may be higher than the vertical level of the top surface of the second channel portion 140b. In some embodiments, the vertical level of the top surface of the word line 160 may be between the vertical level of the top surface of the second channel portion 140b and the vertical level of the top surface of the third channel portion 140c. In some embodiments, a portion of a lower portion of the third channel portion 140c and a portion of an upper portion of the word line 160 may be offset or overlapped to each other. In some embodiments, the vertical level of the bottom surface of the third channel portion 140c may be located below a point corresponding to half of a total height of the word line 160.

In some embodiments, the gate insulating layer 150 may include at least one selected from a high-k dielectric material and a ferroelectric material having a higher dielectric constant than silicon oxide. In some embodiments, the gate insulating layer 150 may include at least one selected from HfO, HfSiO, HfON, HfSiON, LaO, LaAIO, ZrO, ZrSiO, ZrON, ZrSiON, TaO, TiO, BaSrTiO, BaTiO, PZT, STB, BFO, SrTiO, YO, AlO, or PbScTaO.

In some embodiments, the word line 160 may include Ti, TiN, Ta, TaN, W, WN, TiSiN, WSiN, polysilicon, or combinations thereof, but is not limited thereto.

A liner insulating layer 136 and a filling insulating layer 138 may be formed between the two word lines 160a and 160b within one mold opening 130H. The liner insulating layer 136 and the filling insulating layer 138 may have etch selectivity to each other depending on etching conditions. For example, the liner insulating layer 136 may include a nitride-based insulating layer, such as a silicon nitride, and the filling insulating layer 138 may include an oxide-based insulating layer, such as silicon oxide, but are not limited thereto.

A vertical level of a top surface of the liner insulating layer 136 and the vertical level of the top surface of the filling insulating layer 138 may match with each other, but are not limited thereto. For example, the vertical level of the top surface of the liner insulating layer 136 may be higher or lower than the vertical level of the top surface of the filling insulating layer 138. In addition, the vertical level of the top surface of the liner insulating layer 136 and/or the vertical level of the top surface of the filling insulating layer 138 may match the vertical level of the top surface of the gate insulating layer 150. In some embodiments, the vertical level of the top surface of the liner insulating layer 136 and/or the vertical level of the top surface of the filling insulating layer 138 may be higher or lower than the vertical level of the top surface of the gate insulating layer 150.

A second insulating layer 176 may be formed outside of the channel layer 140 formed within one mold opening 130H. The second insulating layer 176 may be formed on the main mold layer 130M. A residual mold layer 130R may be formed between the second insulating layer 176 and the channel layer 140. In some embodiments, the residual mold layer 130R may not be formed between the second insulating layer 176 and the channel layer 140, and in this case, the second insulating layer 176 may contact the channel layer 140. Depending on etching conditions, the second insulating layer 176 and the mold layer 130 may have etch selectivity with respect to each other.

A contact layer 170 may be formed on each third channel portion 140c. The contact layer 170 may contact at least a portion of the third channel portion 140c and thus, may be electrically connected to the third channel portion 140c. In some embodiments, the contact layer 170 may contact a portion of a side wall of the third channel portion 140c as well as the upper surface of the third channel portion 140c. In addition, the contact layer 170 may extend in the second horizontal direction Y so as to contact the upper surface and at least a portion of side wall of the gate insulating layer 150 and the upper surface of the liner insulating layer 136, as well as the upper surface of the third channel portion 140c. For example, as shown in FIG. 3, the contact layer 170 may have an upside-down L-shaped vertical cross-section. In some embodiments, the contact layer 170 may include Ti, TiN, Ta, TaN, W, WN, TiSiN, WSiN, polysilicon, or combinations thereof, but is not limited thereto.

A capping insulating layer 172 may be formed on an upper surface and side walls of the contact layer 170. The capping insulating layer 172 may be formed to cover not only each upper surface and sidewall of a pair of contact layers 170 formed within one mold opening 130H, but also an upper surface of the filling insulating layer 138 between the pair of contact layers 170. As described above, the capping insulating layer 172 may include various insulating materials as long as the capping insulating layer 172 may protect the contact layer 170 during an oxygen annealing treatment for the third channel portion 140c. The capping insulating layer 172 may include an oxide-based insulating layer, a nitride-based insulating layer, or an oxynitride-based insulating layer. For example, the capping insulating layer 172 may include the nitride-based insulating layer, such as a silicon nitride layer.

An oxygen-containing insulating layer 174 may be formed on an exposed surface of the capping insulating layer 172. As will be described later, the oxygen-containing insulating layer 174 may be formed on the exposed surface of the capping insulating layer 172 exposed during the oxygen annealing treatment to form the third channel portion 140c. Therefore, similar to the capping insulating layer 172, the oxygen-containing insulating layer 174 may be formed to cover not only each upper surface and sidewall of the pair of contact layers 170 formed within one mold opening 130H, but also an upper surface of the filling insulating layer 138 between the pair of contact layers 170.

On the other hand, the capping insulating layer 172 and/or the oxygen-containing insulating layer 174 may contact portions of a lower electrode 180. In addition, the capping insulating layer 172 and/or the oxygen-containing insulating layer 174 that are formed on outer side walls of the pair of contact layer 170 formed within one mold opening 130H, may be connected to the capping insulating layer 172 and/or the oxygen-containing insulating layer 174 that are formed on inner side walls and the upper surface of the filling insulating layer 138. The oxygen-containing insulating layer 174 may include an oxide-based insulating layer, a nitride-based insulating layer, or an oxynitride-based insulating layer. For example, the oxygen-containing insulating layer 174 may include an oxide-based insulating layer, such as a silicon oxide layer.

The second insulating layer 176 may be formed between the pair of contact layers 170 and may be formed outside the pair of contact layers 170 in the second horizontal direction Y, in which the pair of contact layers 170 are covered by the oxygen-containing insulating layer 174 and the oxygen-containing insulating layer 174. As described above, the second insulating layer 176 may be formed to fill the outer spaces of the third channel portion 140c. The second insulating layer 176 may serve as a gap fill layer. The second insulating layer 176 may include a nitride-based insulating layer, for example a silicon nitride layer.

A capacitor structure CS may be formed at a top of each contact layer 170. The capacitor structure CS may include the lower electrode 180, a capacitor dielectric layer 182, and an upper electrode 184. The lower electrode 180 may be formed on a removed portion while extending vertically, in which the removed portion may be formed by removing portions of the capping insulating layer 172, the oxygen-containing insulating layer 174, and the second insulating layer 176 that are formed on the upper surface of the contact layer 170, so as to expose a portion of the upper surface of the contact layer 170. One pair of lower electrodes 180, each one of the pair of lower electrodes 180 connected to a respective one of each of the pair of contact layers 170, may be formed to share one upper electrode 184. In some embodiments, one pair of lower electrodes 180 connected to each of the pair of contact layers 170 may be formed to have one upper electrode, respectively.

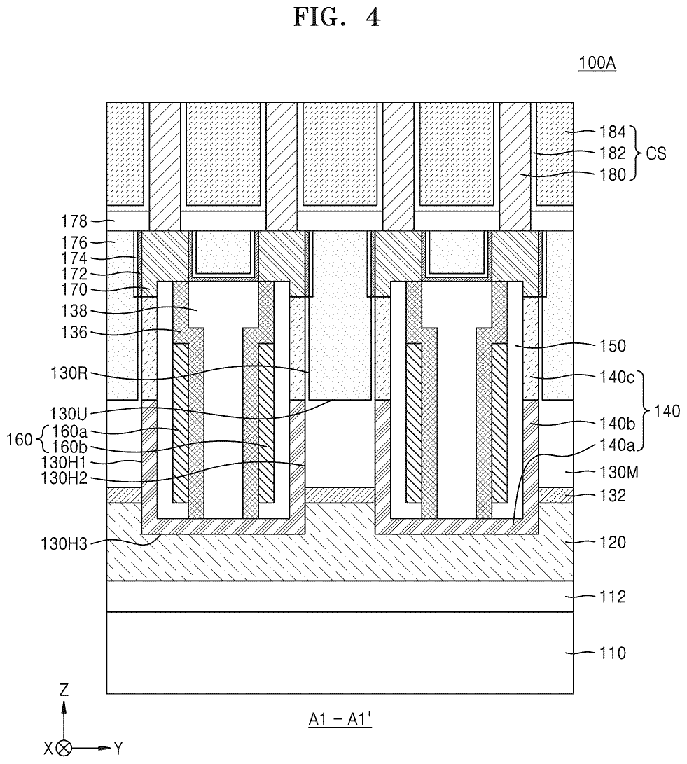

FIG. 4 is a cross-sectional view of a semiconductor device 100A taken along line A1-A1′ in FIG. 2, according to some embodiments. Descriptions that overlap the descriptions with respect to the semiconductor device 100 shown in FIG. 3 will be omitted as much as possible.

Unlike the semiconductor device 100 shown in FIG. 3, the semiconductor device 100A shown in FIG. 4 shows that the vertical levels of upper surfaces of the contact layer 170, the capping insulating layer 172, the oxygen-containing insulating layer 174, and the second insulating layer 176 may be located at the same position. In addition, an etch stop layer 178 may be formed on the upper surfaces of the contact layer 170, the capping insulating layer 172, the oxygen-containing insulating layer 174, and the second insulating layer 176 that are planarized. The lower electrode 180 of the capacitor structure CS may be formed on at least a portion of the upper surface of the contact layer 170 while penetrating the etch stop layer 178. The etch stop layer 178 may include an oxide-based insulating layer, a nitride-based insulating layer, or an oxynitride-based insulating layer, for example a silicon oxide layer.

In the semiconductor device 100A shown in FIG. 4, the vertical level of the top surface of the capping insulating layer 172 and/or the vertical level of the top surface of the oxygen-containing insulating layer 174 may be located below the vertical level of a bottom surface of the lower electrode 180. In addition, the capping insulating layer 172 and/or oxygen-containing insulating layer 174 may not contact the lower electrode 180.

In addition, the capping insulating layer 172 and/or the oxygen-containing insulating layer 174 that are formed on outer side walls of the pair of contact layers 170 formed within one mold opening 130H, may be separated from the capping insulating layer 172 and/or the oxygen-containing insulating layer 174 that are formed on inner side walls and the upper surface of the filling insulating layer 138.

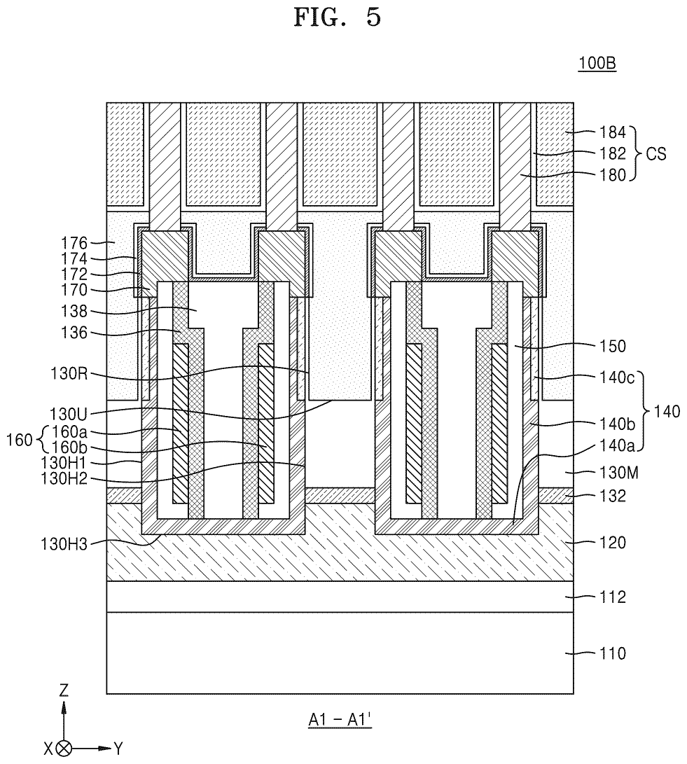

FIG. 5 is a cross-sectional view of a semiconductor device 100B taken along line A1-A1′ in FIG. 2, according to some embodiments. Descriptions that overlap the descriptions with respect to the semiconductor device 100 shown in FIG. 3 will be omitted as much as possible.

Unlike the semiconductor device 100 shown in FIG. 3, in the semiconductor device 100B shown in FIG. 4, the third channel portion 140c, which is the oxygen-rich region, may be formed only on a portion of outer side walls of the channel layer 140 in the second horizontal direction Y. As described above, in the semiconductor device 100 shown in FIG. 3, the third channel portion 140c, which is the oxygen-rich region, may be formed across the entire channel layer 140 in the second horizontal direction Y. For example, a portion of the second channel portion 140b may extend vertically to be adjacent to the third channel portion 140c in the second horizontal direction Y. The portion of the second channel portion 140b that is adjacent to the third channel portion 140c in the second horizontal direction Y may be closer to a center of the mold opening 130H than the third channel portion 140c is.

In the semiconductor device 100B shown in FIG. 5, the third channel portion 140c, which is the oxygen-rich region, may be formed with a certain width in the vertical direction Z along the outer side walls of the channel layer 140. Therefore, the second channel portion 140b and the third channel portion 140c may coexist in an upper side of the channel layer 140 that extends vertically. In some embodiments, the third channel portion 140c may be the oxygen-rich region in which the oxygen concentration in the third channel portion 140c is greater than the oxygen concentration in the second channel portion 140b. In some embodiments, the third channel portion 140c may include an oxide semiconductor material. The oxide semiconductor material may include oxygen, and may include at least one of IGZO, Sn-doped IGZO, W-doped IGZO, IZO, for example. The third channel portion 140c, which is the oxygen-rich region, may have an oxygen concentration greater than those of the first channel portion 140a and the second channel portion 140b. In some embodiments, in the oxygen-rich region, the oxygen concentration may decrease linearly or non-linearly from the outer side wall of the channel layer 140 toward an inner side. In some embodiments, in the oxygen-rich region, the oxygen concentration may decrease linearly by the diffusion distance of oxygen from the outer side wall of the channel layer 140 toward the inner side. In some embodiments, a width of the third channel portion 140c in the second horizontal direction Y may be within the diffusion distance of oxygen. In some embodiments, in the third channel portion 140c, the oxygen concentration profile in the vertical direction Z may have approximately a same oxygen concentration profile with respect to a distance in the second horizontal direction Y from the outer side wall of the third channel portion 140c toward the inner side.

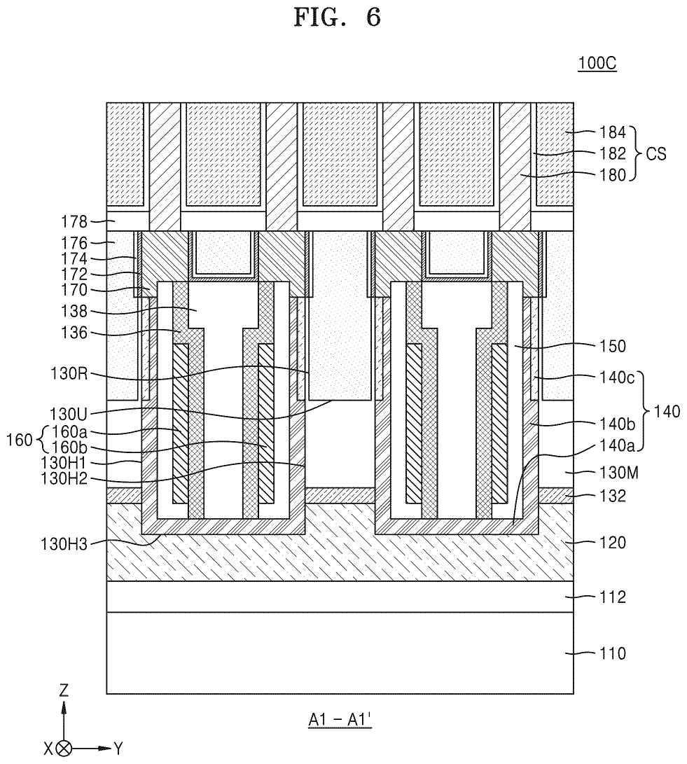

FIG. 6 is a cross-sectional view of a semiconductor device 100C taken along line A1-A1′ in FIG. 2, according to some embodiments. Descriptions that overlap the descriptions with respect to the semiconductor device 100 shown in FIG. 3 will be omitted as much as possible.

Unlike the semiconductor device 100 shown in FIG. 3, the semiconductor device 100C shown in FIG. 6 shows that the vertical levels of upper surfaces of the contact layer 170, the capping insulating layer 172, the oxygen-containing insulating layer 174, and the second insulating layer 176 may be located at the same position. In addition, an etch stop layer 178 may be formed on the upper surfaces of the contact layer 170, the capping insulating layer 172, the oxygen-containing insulating layer 174, and the second insulating layer 176 that are planarized. The lower electrode 180 of the capacitor structure CS may be formed on at least a portion of an upper surface of the contact layer 170 while penetrating the etch stop layer 178.

In addition, in the semiconductor device 100C shown in FIG. 6, the vertical level of the top surface of the capping insulating layer 172 and/or the vertical level of the top surface of the oxygen-containing insulating layer 174 may be located below the vertical level of a bottom surface of the lower electrode 180. In addition, the capping insulating layer 172 and/or oxygen-containing insulating layer 174 may not contact the lower electrode 180. In addition, the capping insulating layer 172 and/or the oxygen-containing insulating layer 174 that are formed on outer side walls of the pair of contact layers 170 formed within one mold opening 130H, may be separated from the capping insulating layer 172 and/or the oxygen-containing insulating layer 174 that are formed on inner side walls and the upper surface of the filling insulating layer 138.

On the other hand, in the semiconductor device 100C shown in FIG. 6, the third channel portion 140c, which is the oxygen-rich region, may be formed on a portion of the outer side walls of the channel layer 140 in the second horizontal direction Y. In addition, in the semiconductor device 100C shown in FIG. 6, the third channel portion 140c, which is the oxygen-rich region, may be formed with a certain width in the the vertical direction Z along the outer side walls of the channel layer 140. Therefore, the second channel portion 140b and the third channel portion 140c may coexist in the upper side of the channel layer 140 that extends vertically. In some embodiments, the third channel portion 140c may be the oxygen-rich region in which the oxygen concentration in the third channel portion 140c is greater than the oxygen concentration in the second channel portion 140b. In some embodiments, the third channel portion 140c may include an oxide semiconductor material. The oxide semiconductor material may include oxygen, and may include at least one of IGZO, Sn-doped IGZO, W-doped IGZO, IZO, for example. The third channel portion 140c, which is the oxygen-rich region, may have an oxygen concentration greater than those of the first channel portion 140a and the second channel portion 140b. In some embodiments, in the oxygen-rich region, the oxygen concentration may decrease linearly or non-linearly from the outer side wall of the channel layer 140 toward an inner side. In some embodiments, in the oxygen-rich region, the oxygen concentration may decrease linearly by the diffusion distance of oxygen from the outer side wall of the channel layer 140 toward the inner side. In some embodiments, the width of the third channel portion 140c in the second horizontal direction Y may be within the diffusion distance of oxygen. In some embodiments, in the third channel portion 140c, the oxygen concentration profile in the vertical direction Z may have approximately a same oxygen concentration profile with respect to a distance in the second horizontal direction Y from the outer side wall of the third channel portion 140c toward the inner side.

FIGS. 7 to 18 are cross-sectional views showing a method of manufacturing a semiconductor device shown in FIG. 3 or 4, according to some embodiments. In FIGS. 7 to 18, the same reference numerals as in FIG. 3 or 4 indicate to the same components.

Referring to FIG. 7, a lower insulating layer 112 may be formed on a substrate 110. Thereafter, a plurality of bit lines 120 extending in the second horizontal direction Y and a bit line insulating layer (not shown) that fills a space between the plurality of bit lines 120, may be formed on the lower insulating layer 112. In some embodiments, each of the plurality of bit lines 120 may include a conductive barrier layer (not shown), the bit line 120, and a conductive barrier layer (not shown) that are arranged sequentially. For example, the bit line insulating layer (not shown) may be formed on the lower insulating layer 112, and then the bit line insulating layer may be patterned using a mask pattern (not shown) to form a space for forming the bit line 120. After forming a conductive layer for forming the bit line 120 in the space for forming the bit line 120, the plurality of bit lines 120 may be formed by removing a portion of an upper side of the conductive layer for forming the bit line until an upper surface of the bit line insulating layer is exposed.

Next, a first insulating layer 132 and a mold layer 130 may be formed sequentially on the bit line 120 and the bit line insulating layer (not shown). The mold layer 130 may be formed to have a relatively large height compared to a height of the first insulating layer 132 in the vertical direction Z using at least one of silicon oxide, silicon nitride, and silicon oxynitride. The first insulating layer 132 and the mold layer 130 may include materials having etch selectivity to each other, respectively.

Referring to FIG. 8, a mask pattern (not shown) may be formed on the mold layer 130, and a plurality of mold openings 130H may be formed using the mask pattern as an etch mask. An upper surface of the bit line 120 may be exposed to a bottom portion 130H3 of the plurality of mold openings 130H. The plurality of mold openings 130H may include a first side wall 130H1 and a second side wall 130H2 facing each other. The mold opening 130H may be formed so that at least a portion of the bit line 120 is recessed and the first insulating layer 132 is fully penetrated. Accordingly, portions of the bit line 120, the first insulating layer 132, and the mold layer 130 may be exposed to the first side wall 130H1 and the second side wall 130H2 of the mold opening 130H, respectively.

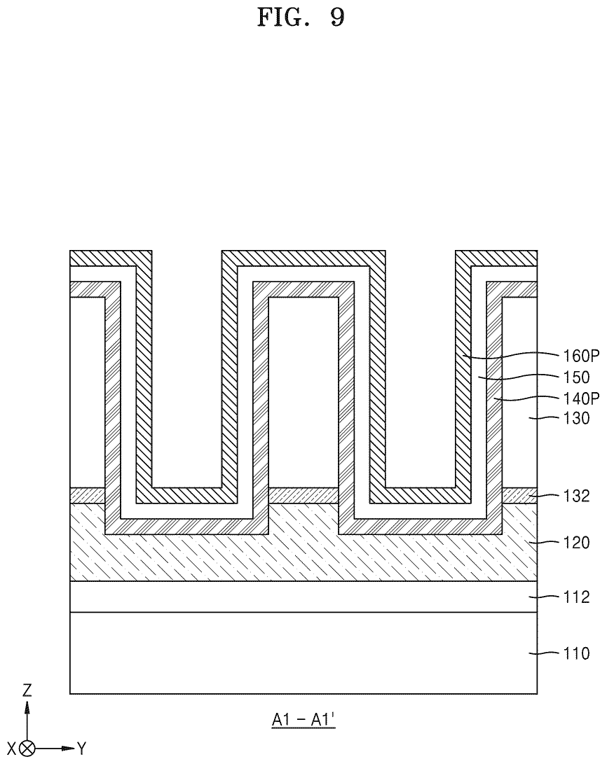

Referring to FIG. 9, a preliminary channel layer 140P, a gate insulating layer 150, and a preliminary word line layer (or a preliminary gate electrode layer) 160P may be respectively formed to conformally cover the bit line 120, the first insulating layer 132, and the mold layer 130 that are exposed to the mold opening 130H.

In some embodiments, the preliminary channel layer 140P may be formed using a first oxide semiconductor material. For example, the oxide semiconductor material may include oxygen, and may include at least one of IGZO, Sn-doped IGZO, W-doped IGZO, IZO, for example. In some embodiments, the preliminary channel layer 140P, the gate insulating layer 150, and the preliminary word line layer 160P may be formed using at least one of a chemical vapor deposition (CVD) process, a low pressure CVD process, a plasma reinforcement CVD process, an organic metal CVD (MOCVD) process, and an atomic layer deposition process. The gate insulating layer 150 may include at least one selected from a high-k dielectric material and a ferroelectric material having a higher dielectric constant than silicon oxide. In some embodiments, the preliminary word line layer 160P may include Ti, TiN, Ta, TaN, W, WN, TiSiN, WSiN, polysilicon, or combinations thereof.

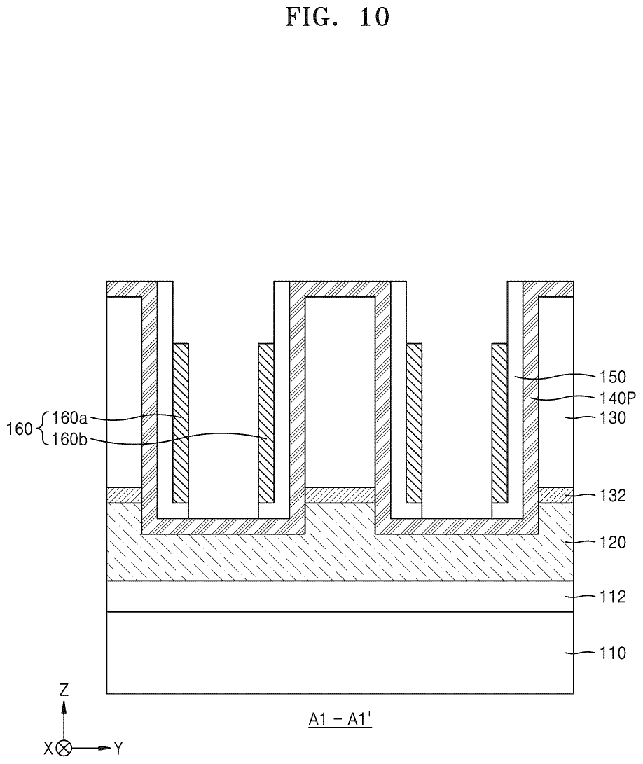

Referring to FIG. 10, by performing an anisotropic etching process on the preliminary word line layer 160P, a portion of the preliminary word line layer 160P that is formed on the bottom portion 130H3 of the mold opening 130H may be removed to form the word line 160 on the first side wall 130H1 and the second side wall 130H2 of the mold opening 130H. On the other hand, all of the preliminary word line layer 160P located on the upper surface of the mold layer 130 may be removed by the anisotropic etching process. For example, the word line 160 may be separated into two first and second word lines 160a and 160b formed on the first side wall 130H1 and the second side wall 130H2 of the mold opening 130H, respectively. At this time, a portion of the upper side of the word line 160 may be also removed, and the vertical level of the top surface of the word line 160 may be lower than the vertical level of the top surface of the mold layer 130.

In addition, a portion of the gate insulating layer 150 formed on the bottom portion 130H3 of the mold opening 130H may be removed to expose the preliminary channel layer 140P. In some embodiments, the gate insulating layer 150 formed on the bottom portion 130H3 of the mold opening 130H may remain without being removed. In addition, the gate insulating layer 150 located on the upper surface of the mold layer 130 may be removed by the anisotropic etching process, and an upper surface of the preliminary channel layer 140P may be exposed.

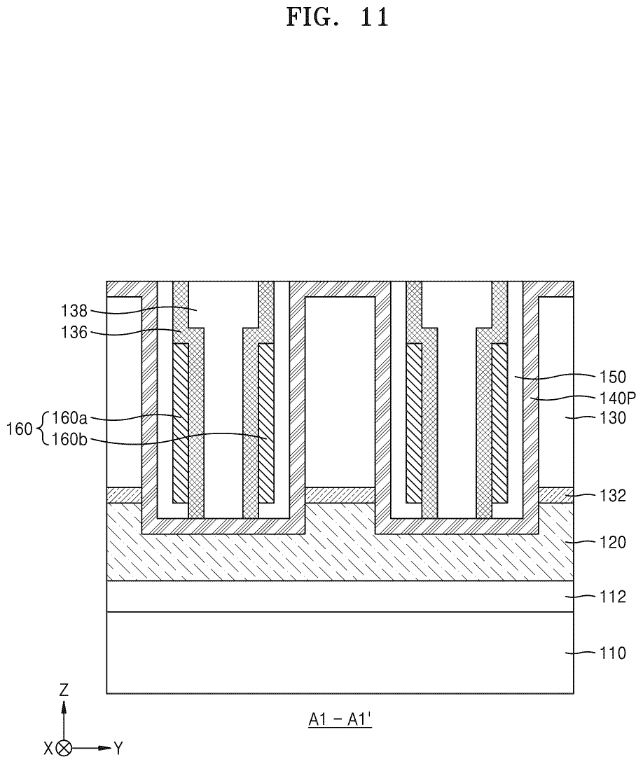

Referring to FIG. 11, a liner insulating layer 136 and a filling insulating layer 138 may be formed on an entire surface of the result of FIG. 10. When a surface planarization process is performed, the liner insulating layer 136 and the filling insulating layer 138 may be formed between two adjacent word lines 160a and 160b in the mold opening 130H.

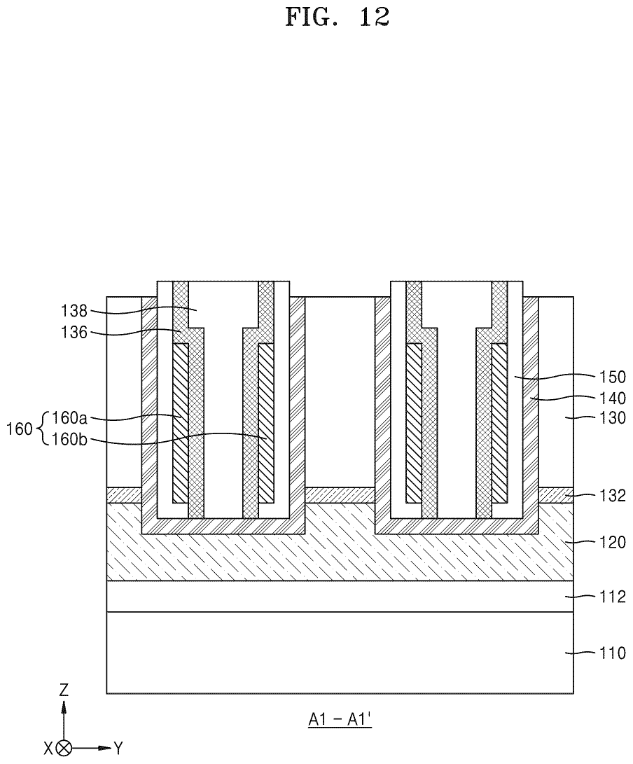

Referring to FIG. 12, a portion of the preliminary channel layer 140P formed on the upper surface of the mold layer 130 may be removed by an etch back process or a planarization process to leave the channel layer 140 in the mold opening 130H.

The channel layer 140 having a U-shaped vertical cross-section may be formed in the mold opening 130H by the etch back process or the planarization process. In addition, as the preliminary channel layer 140P located on the upper surface of the mold layer 130 is removed, the upper surface of the mold layer 130 may be exposed.

In some embodiments, the channel layer 140 may include a first channel portion 140a extending in the second horizontal direction Y and a second channel portion 140b connected to both ends of the first channel portion 140a and extending therefrom in the vertical direction Z (see, e.g., FIG. 3). In addition, the upper surface of the channel layer 140 may be located at the same level as the upper surface of the mold layer 130.

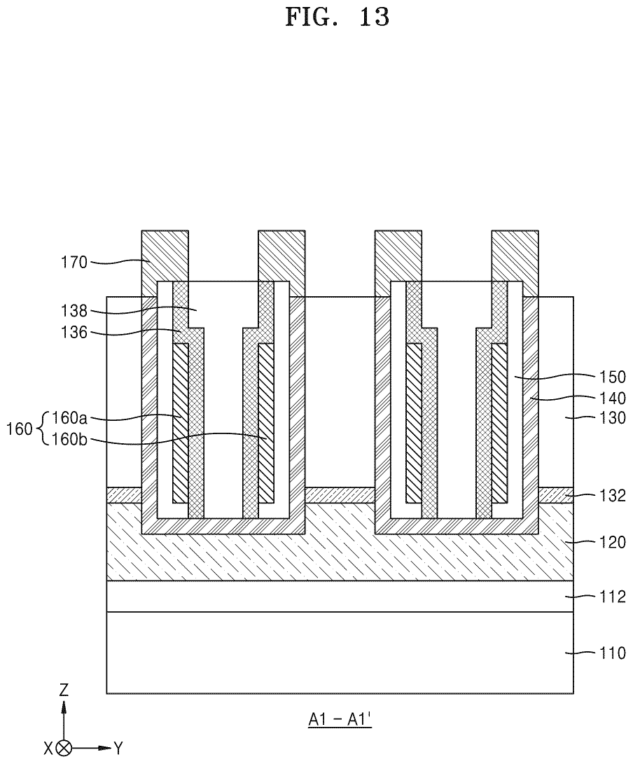

Referring to FIG. 13, after forming a material layer for forming a contact layer on an entire surface of the device as shown in FIG. 12, a contact layer 170 may be formed on an upper side of the channel layer 140 through a photolithography process. As shown in FIG. 3, the contact layer 170 may be formed to extend to the upper surfaces of the gate insulating layer 150 and the liner insulating layer 136 as well as the upper surface of the channel layer 140.

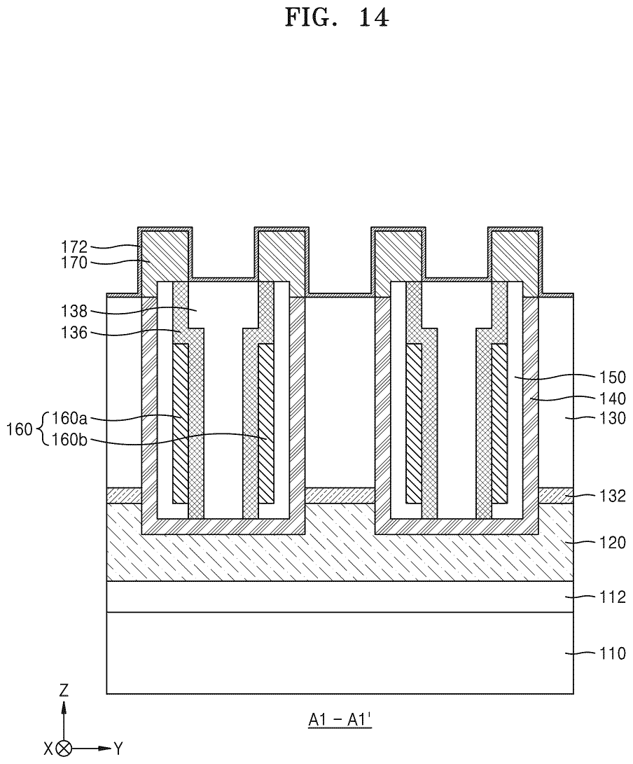

Referring to FIG. 14, a capping insulating layer 172 may be formed on an entire surface of the result of FIG. 13.

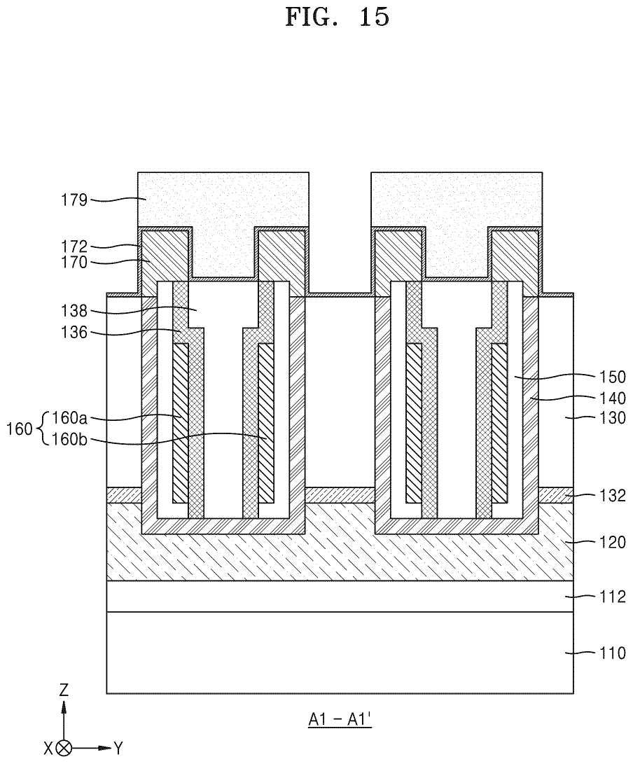

Referring to FIG. 15, a mask material layer may be formed on an entire surface of FIG. 14 on which the capping insulating layer 172 is formed, and then a mask pattern 179 may be formed through a patterning process. The mask pattern 179 may expose an upper side of the mold layer 130 remaining between adjacent mold openings 130H, while covering a pair of contact layers 170 and the mold layer 130 between the pair of contact layers 170 that are formed within one mold opening 130H.

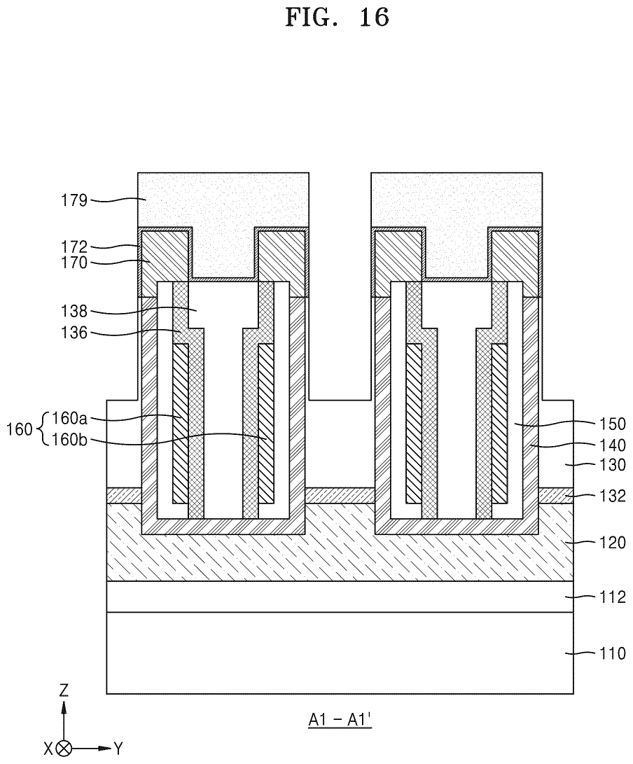

Referring to FIG. 16, an etching process may be performed using the mask pattern 179 as an etch mask to remove the capping insulating layer 172 exposed by the mask pattern 179 and a portion of the mold layer 130 located below the capping insulating layer 172 and exposed by the mask pattern 179. As a result of the etching process, a portion of an upper side of the channel layer 140 may be exposed. The etching process may be performed so that an upper side wall of the channel layer 140 may be completely exposed, but in some embodiments, a thin residual mold layer 130R (see FIG. 3) may remain on the upper side wall of the channel layer 140. A thickness of the residual mold layer 130R may be within a range that may effectively perform an oxygen annealing treatment in a Vo passivation process, as described later. On the other hand, a vertical level of a top surface of the main mold layer 130M (see FIG. 3) remaining after the etching process of the mold layer 130, may be located below the vertical level of the top surface of the word line 160.

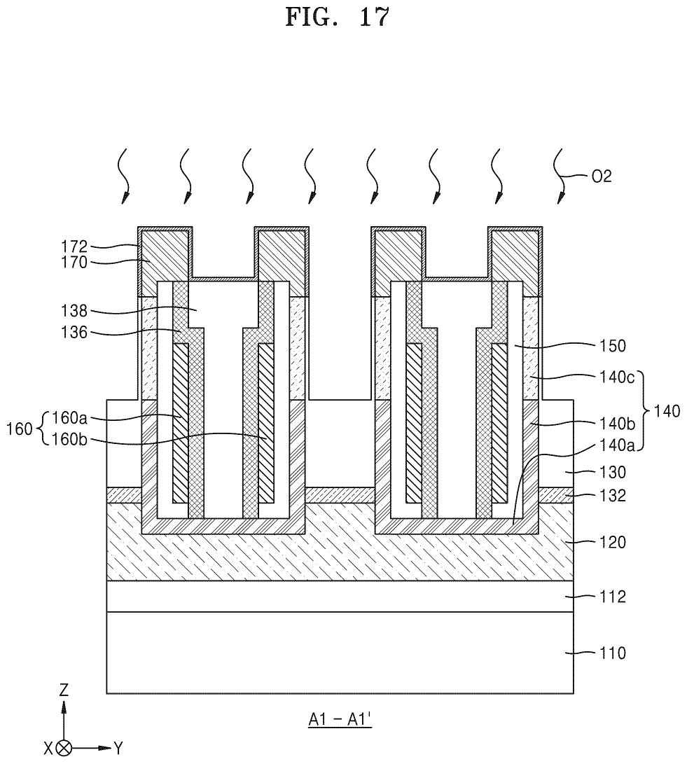

Next, referring to FIG. 17, the mask pattern 179 may be removed and the oxygen annealing treatment may be performed on the semiconductor device. At this time, the diffusion of oxygen may actively proceed on the upper side of the channel layer 140 that is not covered by the capping insulating layer 172 and the main mold layer 130M. In this case, even though the residual mold layer 130R remains thinly on the upper side wall of the channel layer 140, the diffusion of oxygen may not be interfered. The oxygen annealing treatment may be performed at a temperature ranging from about 300° C. to about 500° C. for tens of minutes to tens of hours, for example, in a range of about 30 minutes to about 30 hours.

As a result of the oxygen annealing treatment, the oxygen concentration in a third channel portion 140c that is located on the upper side of the channel layer 140 including an oxide semiconductor material may be greater than that in other portions of the channel layer 140 (e.g., the first channel portion 140a and the second channel portion 140b), and thus diffused oxygen atoms may penetrate into oxygen vacancy sites within the channel layer 140, thereby lowering the oxygen vacancy concentration. Accordingly, leakage current caused by oxygen vacancies within the channel layer 140 may decrease.

The oxygen annealing treatment may be performed until the diffusion of oxygen is sufficiently proceeded in the second horizontal direction Y over the entire upper portion of the channel layer 140. On the other hand, an oxygen-containing insulating layer 174 may be formed on the exposed surface of the capping insulating layer 172 exposed during the oxygen annealing treatment to form the third channel portion 140c.

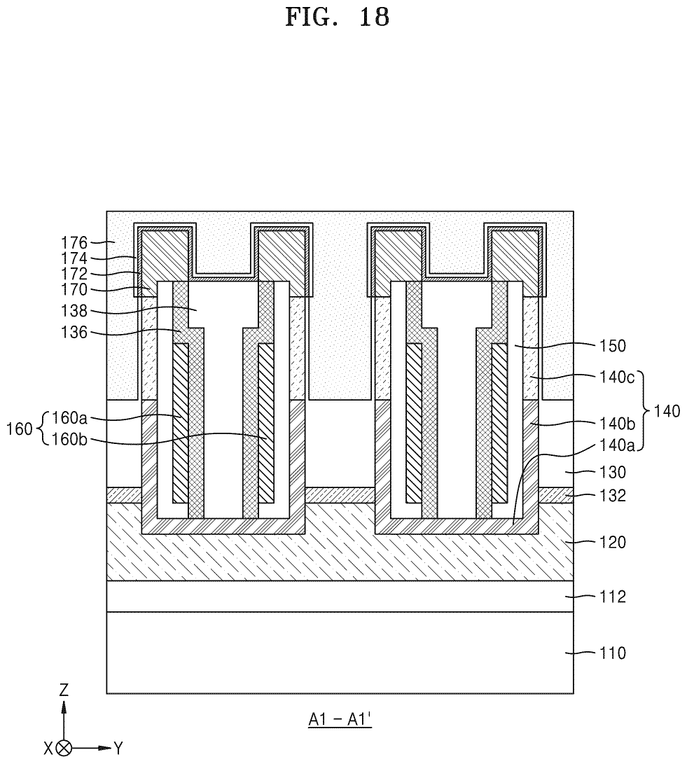

Referring to FIG. 18, after performing the oxygen annealing treatment, a second insulating layer 176 may be formed on an entire surface of the result of FIG. 17.

Referring to FIG. 3 again, after removing portions of the second insulating layer 176, the oxygen-containing insulating layer 174, and the capping insulating layer 172 to expose the contact layer 170, a capacitor structure CS may be formed.

In some embodiments, referring back to FIG. 4, portions of the second insulating layer 176, the oxygen-containing insulating layer 174, and the capping insulating layer 172 may be removed until the upper surface of the contact layer 170 is exposed and then an etch stop layer 178 may be formed on the result of FIG. 18. Next, a portion of the etch stop layer 178 may be removed to expose a portion of the contact layer 170, and the capacitor structure CS connected to the contact layer 170 may be formed.

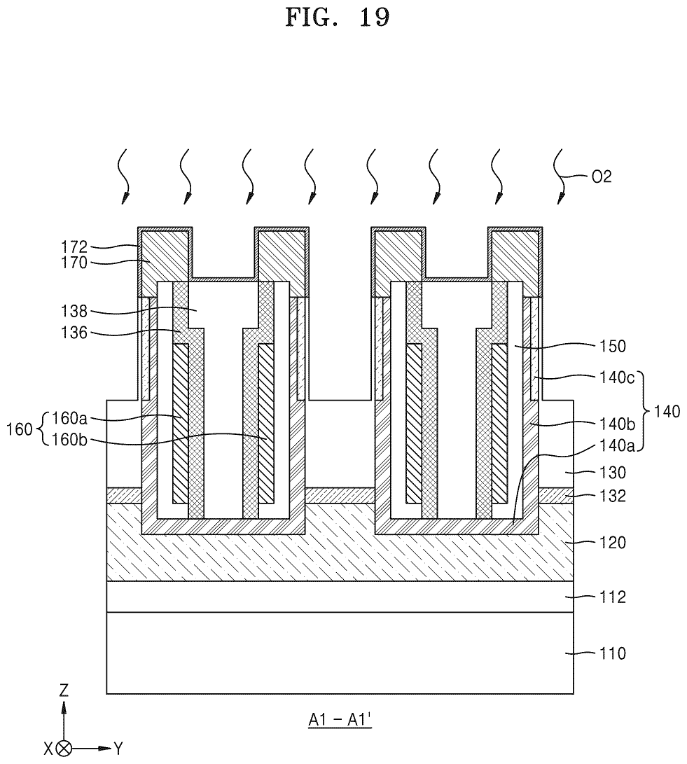

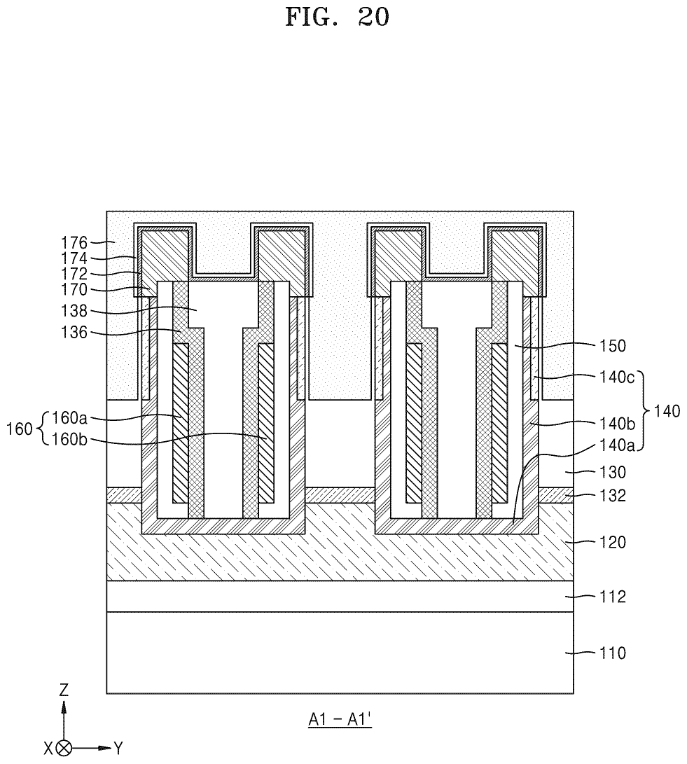

FIGS. 19 and 20 are cross-sectional views showing a method of manufacturing a semiconductor device shown in FIG. 5 or 6, according to some embodiments. The manufacturing method of FIGS. 7 to 16 may be applied in the same manner and duplicated descriptions will be omitted.

Following FIG. 16, referring to FIG. 19, the mask pattern 179 may be removed and the oxygen annealing treatment may be performed on the semiconductor device. At this time, the oxygen annealing treatment may be performed by adjusting process conditions to the extent that the diffusion of oxygen occurs only in some regions along the outer side wall of the channel layer 140 on the upper side of the channel layer 140.

As a result of the oxygen annealing treatment, the oxygen concentration in a third channel portion 140c that is located near the outer side wall of the upper side of the channel layer 140 including an oxide semiconductor material may be greater than that in other portions of the channel layer 140 (e.g., the first channel portion 140a and the second channel portion 140b), and thus diffused oxygen atoms may penetrate into oxygen vacancy sites within the channel layer 140, thereby lowering the oxygen vacancy concentration. Accordingly, leakage current caused by oxygen vacancies within the channel layer 140 may decrease.

The oxygen annealing treatment may be performed until the diffusion of oxygen is partially proceeded in the second horizontal direction Y over a portion of the upper side of the channel layer 140. On the other hand, an oxygen-containing insulating layer 174 may be formed on the exposed surface of the capping insulating layer 172 exposed during the oxygen annealing treatment to form the third channel portion 140c. Accordingly, the second channel portion 140b and the third channel portion 140c may coexist in the upper side (e.g., the upper portion) of the channel layer 140.

Referring to FIG. 20, after performing the oxygen annealing treatment, a second insulating layer 176 may be formed on an entire surface of the result of FIG. 19.

Next, referring back to FIG. 3, after removing portions of the second insulating layer 176, the oxygen-containing insulating layer 174, and the capping insulating layer 172 to expose the contact layer 170, and then a capacitor structure CS may be formed.

In some embodiments, referring back to FIG. 6, portions of the second insulating layer 176, the oxygen-containing insulating layer 174, and the capping insulating layer 172 may be removed until the upper surface of the contact layer 170 is exposed and then an etch stop layer 178 may be formed on the result of FIG. 20. Next, a portion of the etch stop layer 178 may be removed to expose a portion of the contact layer 170, and the capacitor structure CS connected to the contact layer 170 may be formed.

While the inventive concept has been particularly shown and described with reference to embodiments thereof, it will be understood that various changes in form and details may be made therein without departing from the spirit and scope of the following claims.

What is claimed is:

1. A semiconductor device comprising:
a bit line extending in a first horizontal direction on a substrate;
a channel layer on the bit line and extending in a vertical direction;
a word line adjacent to a side wall of the channel layer and extending in a second horizontal direction crossing the first horizontal direction;
a gate insulating layer between the channel layer and the word line;
a contact layer on an upper side of the channel layer;
a capping insulating layer covering at least a portion of the contact layer;
an oxygen-containing insulating layer on at least a portion of the capping insulating layer; and
a capacitor comprising a lower electrode that contacts at least a portion of an upper surface of the contact layer.

2. The semiconductor device of claim 1, wherein the oxygen-containing insulating layer contacts at least a portion of the lower electrode of the capacitor.

3. The semiconductor device of claim 2, wherein
the capping insulating layer is formed on at least a portion of a side wall of the contact layer and at least a portion of the upper surface of the contact layer, and
the capping insulating layer contacts at least a portion of the lower electrode of the capacitor.

4. The semiconductor device of claim 1, wherein the oxygen-containing insulating layer does not contact the lower electrode of the capacitor.

5. The semiconductor device of claim 1, wherein
a vertical level of a top of the oxygen-containing insulating layer is below a vertical level of a bottom of the lower electrode of the capacitor.

6. The semiconductor device of claim 1, wherein
the channel layer comprises an oxygen-rich region in an upper portion of the channel layer, the oxygen-rich region having an oxygen concentration greater than an oxygen concentration at a lower portion of the channel layer.

7. The semiconductor device of claim 6, wherein
the oxygen-rich region of the channel layer is formed from a surface of an outer side wall of the channel layer to an inner portion of the channel layer in the first horizontal direction.

8. The semiconductor device of claim 6, wherein
a vertical level of a bottom of the oxygen-rich region of the channel layer is located below a vertical level of a top of the word line.

9. The semiconductor device of claim 1, wherein
the channel layer comprises at least one of InGaZnOx (IGZO), Sn-doped IGZO, W-doped IGZO, and InZnOx (IZO).

10. The semiconductor device of claim 1, wherein
the capping insulating layer comprises a nitride-based insulating layer, and
the oxygen-containing insulating layer comprises an oxide-based insulating layer.

11. A semiconductor device comprising:
a bit line extending in a first horizontal direction on a substrate;
a channel layer having a U-shape with a pair of opposing vertical extending portions that extend in a vertical direction on the bit line, wherein the pair of vertical extending portions each have an inner side wall and an outer side wall, the inner side wall of one of the pair of vertical extending portions facing the inner side wall of the other of the pair of vertical extending portions;
a main mold layer covering at least a portion of the outer side wall of each of the pair of vertical extending portions of the channel layer, wherein a vertical level of a top surface of the main mold layer is below a vertical level of a top surface of the pair of vertical extending portions of the channel layer;
a pair of word lines, each word line of the pair of word lines being adjacent to the inner side wall of a respective vertical extending portion of the pair of vertical extending portions, and extending in a second horizontal direction;
a pair of gate insulating layers, each gate insulating layer of the pair of gate insulating layers being between the inner side wall of a respective vertical extending portion and a respective word line of the pair of word lines;
a filling insulating layer between the pair of word lines;
a pair of contact layers, each contact layer of the pair of contact layers being formed on an upper surface of a respective vertical extending portion of the channel layer; and
capacitor structures each comprising a lower electrode contacting at least a portion of each contact layer of the pair of contact layers, respectively, wherein
the channel layer comprises an oxygen-rich region in an upper portion of the channel layer, and the oxygen-rich region has an oxygen concentration greater than the oxygen concentration at a lower portion of the channel layer.

12. The semiconductor device of claim 11, wherein
a vertical level of a top surface of the word line is between the vertical level of the top surface of the vertical extending portion of the channel layer and the vertical level of the top surface of the main mold layer.

13. The semiconductor device of claim 11, further comprising
a residual mold layer formed on the outer side wall of the upper portion of each vertical extending portion of the pair of vertical extending portions of the channel layer that is not surrounded by the main mold layer.

14. The semiconductor device of claim 11, further comprising:
a capping insulating layer covering at least a portion of each contact layer of the pair of contact layers; and
an oxygen-containing insulating layer formed on at least a portion of the capping insulating layer.

15. The semiconductor device of claim 14, wherein
the oxygen-containing insulating layer contacts at least a portion of the lower electrode of each of the capacitor structures.

16. The semiconductor device of claim 14, wherein
for each capacitor structure of the capacitor structures, the capping insulating layer and the oxygen-containing insulating layer do not contact the lower electrode of the capacitor structure, and
the capping insulating layer and the oxygen-containing insulating layer are also formed on the filling insulating layer.

17. The semiconductor device of claim 11, wherein
the oxygen-rich region of the channel layer is formed along the outer side wall of each vertical extending portion of the pair of vertical extending portions.

18. A semiconductor device comprising:
a bit line extending in a first horizontal direction on a substrate;
a channel layer comprising an oxide semiconductor material, the channel layer having a U-shape with a pair of opposing vertical extending portions that extend in a vertical direction on the bit line, wherein each of the pair of vertical extending portions has an inner side wall and an outer side wall, the inner side wall facing the inner side wall of the other one of the pair of vertical extending portions, and the channel layer comprises a first oxide semiconductor channel layer and a second oxide semiconductor channel layer formed on the first oxide semiconductor channel layer and having an oxygen concentration greater than that of the first oxide semiconductor channel layer;
a main mold layer surrounding at least a portion of the outer side wall of each vertical extending portion of the pair of vertical extending portions of the channel layer, wherein a vertical level of a top surface of the main mold layer is below a vertical level of a top surface of the pair of vertical extending portions of the channel layer;
a pair of opposing word lines that are adjacent to the opposing inner side walls of the channel layer, respectively, the pair of opposing word lines extending in a second horizontal direction;
gate insulating layers, each gate insulating layer of the gate insulating layers being between the inner side wall of a respective vertical extending portion of the pair of vertical extending portions and a respective word line of the pair of word lines;
a filling insulating layer between the pair of word lines;
contact layers formed on an upper surface of each vertical extending portion of the pair of vertical extending portions of the channel layer;
a capping insulating layer covering at least a portion of the contact layers;
an oxygen-containing insulating layer formed on at least a portion of the capping insulating layer; and
capacitor structures each comprising a lower electrode that respectively contact at least a portion of upper surfaces of the contact layers.

19. The semiconductor device of claim 18, wherein
the oxygen-containing insulating layer contacts at least a portion of the lower electrode of each of the capacitor structures.

20. The semiconductor device of claim 18, wherein
the capping insulating layer and the oxygen-containing insulating layer do not contact the lower electrode of each of the capacitor structures, and
the capping insulating layer and the oxygen-containing insulating layer are formed on the filling insulating layer.
